(19) United States
(12) Patent Application Publication
(10) Pub. No.: US 2013/0270636 A1
(43) Pub. Date: Oct. 17, 2013

(54) Transistor Having An Isolated Body For High Voltage Operation

(71) Applicant: Akira Ito, Irvine, CA (US)

(72) Inventor: Akira Ito, Irvine, CA (US)

(73) Assignee: BROADCOM CORPORATION, Iriven, CA (US)

(21) Appl. No.: 13/448,600

(22) Filed: Apr. 17, 2012

(51) Int. Cl. H01L 29/78

(52) U.S. Cl. 257/336; 257/E29.256

(57) ABSTRACT

The present application discloses various implementations of a transistor having an isolated body for high voltage operation. In one exemplary implementation, such a transistor comprises a deep well implant having a first conductivity type disposed in a substrate having a second conductivity type opposite the first conductivity type. The transistor includes a source-side well and a drain-side well of the first conductivity type. The source-side well and the drain-side well are electrically coupled to the deep well implant. The deep well implant, the source-side well, and the drain-side well electrically isolate a body of the transistor from the substrate.

### BACKGROUND

Complementary metal-oxide-semiconductor (CMOS) technology is widely used to provide control logic in modern electronics. Standard CMOS logic transistors are typically low voltage devices. On the other hand, power transistors, such as those providing power switching and voltage regulation, are typically higher voltage versions of metal-oxide-semiconductor field-effect transistors (MOSFETs), such as lateral diffused metal-oxide-semiconductor (LDMOS) transistors. Often, the high voltage power transistors are fabricated alongside the CMOS logic transistors on the same semiconductor die.

As the performance requirements for modern electronic systems grow more stringent, factors affecting device density and noise sensitivity become increasingly important. In addition, in power applications such as voltage regulation, the presence of low voltage CMOS transistors and high voltage MOSFETs on the same semiconductor die may pose significant challenges to use of the high voltage MOSFETs as switches.

### SUMMARY

The present disclosure is directed to a transistor having an isolated body for high voltage operation, as shown in and/or described in connection with at least one of the figures, and as set forth more completely in the claims.

### BRIEF DESCRIPTION OF THE DRAWINGS

FIG. 1 shows a cross-sectional view of a lateral diffused metal-oxide-semiconductor (LDMOS) transistor.

FIG. 2A shows a cross-sectional view of one exemplary implementation of an LDMOS transistor having an isolated body for high voltage operation.

FIG. 2B shows a cross-sectional view of a portion of an exemplary semiconductor die including a low voltage transistor and the LDMOS transistor shown in FIG. 2A.

FIG. 3 shows a cross-sectional view of another exemplary implementation of an LDMOS transistor having an isolated body for high voltage operation.

FIG. 4 shows a cross-sectional view of yet another exemplary implementation of an LDMOS transistor having an isolated body for high voltage operation.

FIG. 5 shows a diagram of an exemplary electronic system including an exemplary semiconductor die utilizing at least one transistor having an isolated body for high voltage operation.

### DETAILED DESCRIPTION

The following description contains specific information pertaining to implementations in the present disclosure. The drawings in the present application and their accompanying detailed description are directed to merely exemplary implementations. Unless noted otherwise, like or corresponding elements among the figures may be indicated by like or corresponding reference numerals. Moreover, the drawings and illustrations in the present application are generally not to scale, and are not intended to correspond to actual relative dimensions.

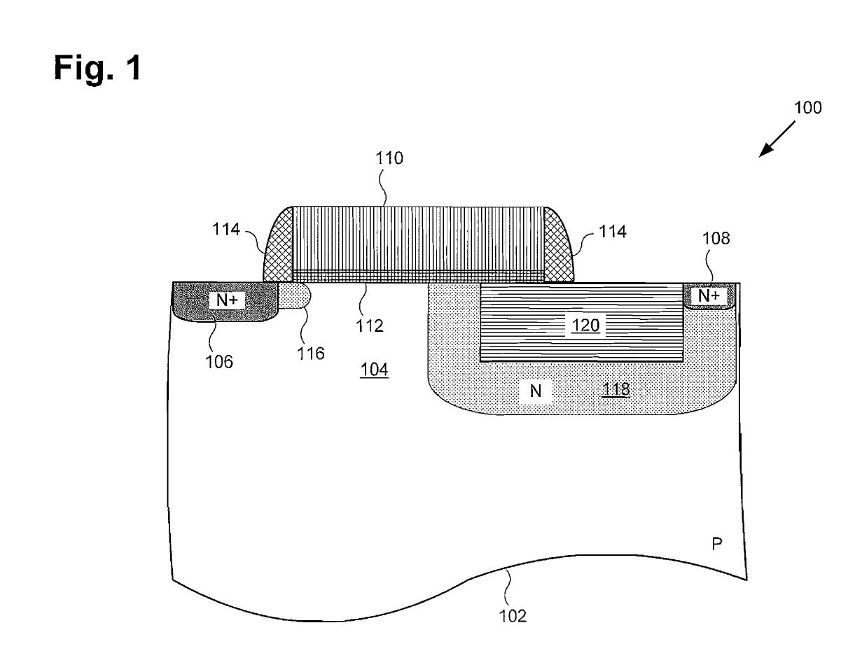

FIG. 1 shows a cross-sectional view of a lateral diffused metal-oxide-semiconductor (LDMOS) transistor 100. The LDMOS transistor 100, which is represented as an n-channel metal-oxide-semiconductor (NMOS) field-effect transistor (FET), is fabricated in a P type substrate 102 of a semiconductor wafer or die. The LDMOS transistor 100 includes a source 106, a source extension 116, a drain 108, and a drain extension well 118 including a shallow trench isolation (STI) body 120. The LDMOS transistor 100 also includes a gate structure including a gate 110 disposed over a gate dielectric layer 112, and spacers 114. The LDMOS transistor 100 further includes a body region 104 disposed under the gate structure and also disposed between the source extension 116 and the drain extension well 118. According to the implementation shown by FIG. 1, the source extension 116, the drain extension well 118, and the STI body 120 extend under the gate 110.

The combination of the STI body 120 and the drain extension well 118 enable the LDMOS transistor 100 to have a higher breakdown voltage than a standard symmetrically configured MOSFET. More specifically, the increased resistance from the drain 108 to the source 106 resulting from the presence of the drain extension well 118 and the STI body 120 renders the LDMOS transistor 100 more resistant to voltage breakdown phenomena. For example, LDMOS 100 is less susceptible to avalanche breakdown and punch-through when compared to standard symmetrically configured MOSFETs.

Despite the higher breakdown voltage of the LDMOS transistor 100 when compared to standard symmetrically configured MOSFETs, implementation of the LDMOS transistor 100 as a high-side switch may be impracticable in some instances. That may be the case if low voltage complementary-metal-oxide-semiconductor (CMOS) devices are also fabricated in the P type substrate 102. As shown in FIG. 1, the source 106 forms a p-n junction with the P type substrate 102, while the body region 104 is electrically tied to the P type substrate 102. As a result, the source 106 and the body region 104 cannot be pulled high without affecting other devices disposed in the P type substrate 102. Moreover, even when utilized as a low-side switch, the relatively higher voltage operation of the LDMOS 100 may generate noise sufficient to affect the performance of low voltage CMOS devices fabricated in the P type substrate 102. For example, the LDMOS device 100 operating at voltages of approximately 3V to approximately 5V may produce undesirable noise levels for CMOS logic devices operating at approximately 1V.

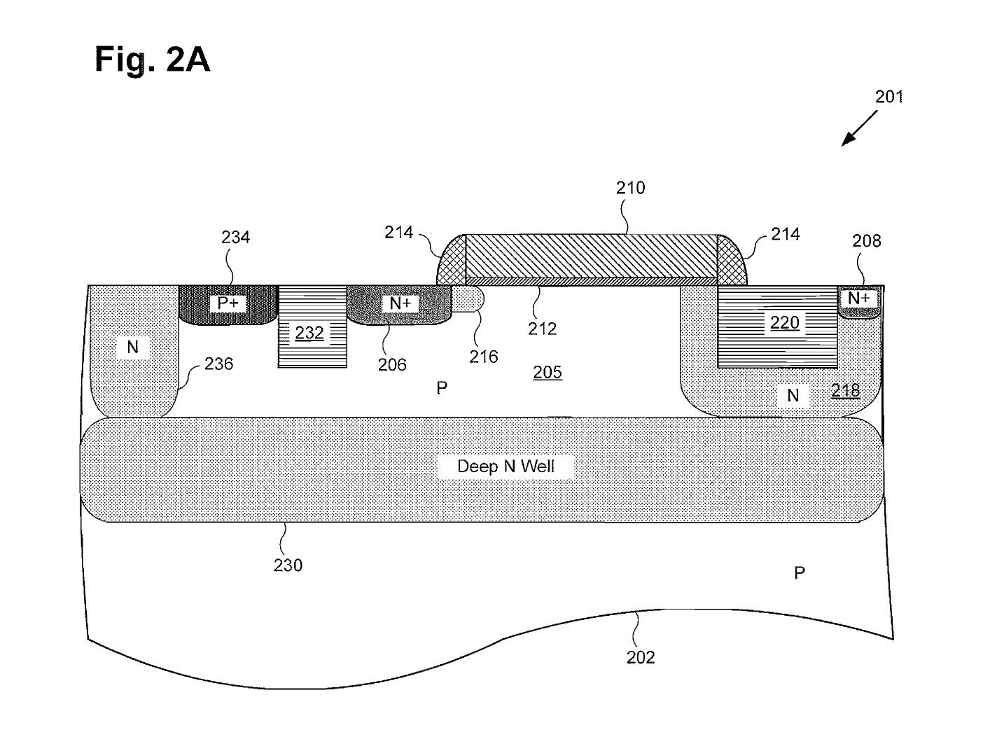

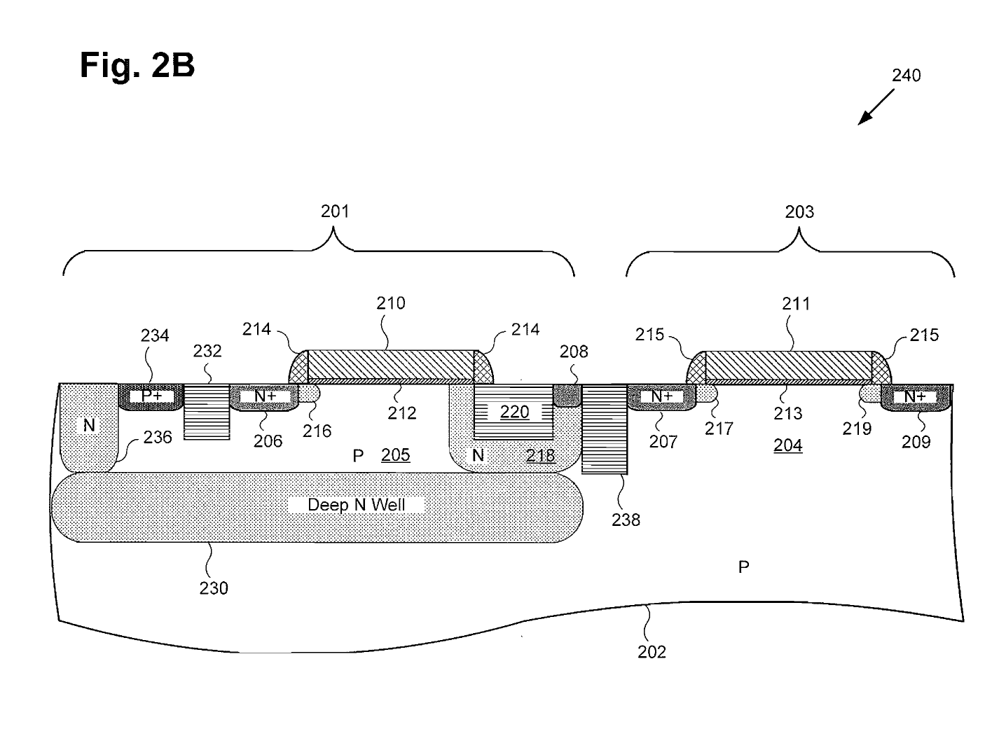

Moving to FIG. 2A, FIG. 2A shows a cross-sectional view of one exemplary implementation of an LDMOS transistor 201 having an isolated body 205 for high voltage operation. The LDMOS transistor 201, which may be implemented as an NMOS or p-channel MOS (PMOS) device, is suitable for use in analog or radio frequency (RF) applications, such as in a cellular telephone power amplifier (PA). Other exemplary applications for the LDMOS transistor 201 include use in a power management unit (PMU), or use in a wireless local area network power amplifier (WLAN PA).

It is emphasized that the specific features represented in FIG. 2A are provided as part of an exemplary implementation, and are shown with such specificity as an aid to conceptual clarity. Because of the emphasis on conceptual clarity, it should be understood that the structures and features depicted in FIG. 2A, as well as subsequent FIGS. 2B, 3, 4, and 5 may not be drawn to scale. Furthermore, particular details such as the type of semiconductor device represented by the LDMOS transistor 201, its overall layout, and the particular dimensions attributed to its features are merely provided as examples. Moreover, although the implementation shown in FIG. 2A characterizes the LDMOS transistor 201 as an NMOS device, more generally, a semiconductor device according to the present inventive principles can be implemented as either an NMOS or a PMOS device. Furthermore, in some implementations, the principles disclosed by the present application can be implemented to fabricate one or more fundamentally distinct device types, such as a BiCMOS device.

As shown in FIG. 2A, the LDMOS transistor 201 is fabricated in a P type substrate 202 of a semiconductor wafer or die. The P type substrate 202 may be a P well formed in a semiconductor wafer or die, or a P type epitaxial layer grown on the semiconductor wafer or die. The LDMOS transistor 201 includes a source 206, a source extension 216, a drain 208, a drain-side N well 218 serving as a drain extension region, and a drain-side isolation body 220 disposed in the drain-side N well 218. The LDMOS transistor 201 also includes a gate 210 disposed over a gate dielectric layer 212, and spacers 214 adjoining the respective source-side and drain-side termini of the gate 210. According to the implementation shown by FIG. 2A, the source extension 216 and the drain-side N well 218 extend under the gate 210. However, the drain-side isolation body 220 is shown as being aligned with the drain-side terminus of the gate 210, and consequently does not extend under the gate 210.

The LDMOS transistor 201 is further shown to include a source-side N well 236, and a deep N well implant 230 electrically coupled to the source-side N well 236 and the drain-side-side N well 218. The electrically coupled arrangement of the deep N well implant 230, the source-side N well 236, and the drain-side N well 218 provides electrical isolation for the isolated body 205. As a result, the P type isolated body 205 is electrically isolated from the P type substrate 202. The electrically coupled arrangement of the deep N well implant 230, the source-side N well 236, and the drain-side N well 218 may also shield other devices fabricated on the P type substrate 202 from noise. For example, the isolated body 205 may result in CMOS logic devices fabricated in the P type substrate 202 being substantially shielded from noise generated by the LDMOS transistor 201 operating at voltages of approximately 3V to approximately 5V. Also shown in FIG. 2A are a source-side isolation body 232 disposed between the source 206 and the source-side N well 236, and a body contact 234 disposed between the source-side isolation body 232 and the source-side N well 236.

The source 206 and the drain 208 are depicted as heavily doped N type regions, and may be produced through implantation of the P type isolated body 205 with an N type dopant such as arsenic (As) or phosphorus (P). The gate 210 may be fabricated of conductive polycrystalline silicon (polysilicon), which may be lightly (e.g., LDD) doped or heavily doped. Other examples of suitable gate materials are gate metals, which in the case of an NMOS implementation may include metals such as tantalum (Ta), tantalum nitride (TaN), or titanium nitride (TiN).

The gate 210 is disposed over the gate dielectric layer 212, which may be implemented as a gate oxide such as silicon dioxide (SiO₂). Other examples of suitable gate dielectric materials for use as the gate dielectric layer 212 in combination with a highly doped polysilicon gate may include silicon nitride (Si₃N₄) or an oxynitride. Example dielectric materials suitable for use as the gate dielectric layer 212 in combination with an LDD doped polysilicon gate, or a metal gate, include high dielectric constant (high-k) metal oxides such as hafnium oxide (HfO₂), zirconium oxide (ZrO₂). It is noted that the characterization “high-k dielectric” refers to a dielectric material having a dielectric constant higher than the dielectric constant of silicon dioxide, such as a dielectric constant of ten (10), or greater. The spacers 214 may be fabricated of any suitable dielectric material using any suitable technique, as known in the art. For example, the spacers 214 may be formed of silicon dioxide or silicon nitride using a chemical vapor deposition (CVD) process.

The deep N well implant 230, the source-side N well 236, the source extension 216, and the drain-side N well 218 may be lightly doped N type regions produced through implantation of P type substrate 202 with an N type dopant such as arsenic or phosphorus. The source-side isolation body 232 and the drain-side isolation body 220 may be fabricated of any suitable dielectric material, and may be STI structures formed of silicon dioxide or tetraethyl orthosilicate (TEOS). The body contact 234 is depicted as a heavily doped P type region, and may be produced through implantation of the P type isolated body 205 with a P type dopant such as boron (B). The body contact 234 may be used to bias the isolated body 205 for operation at a high (or low) voltage relative to the P type substrate 202, as well as relative to other devices fabricated in the P type substrate 202. Consequently, the LDMOS transistor 201 having the isolated body 205 can be used for high voltage operation such as for a high-side switch.

The LDMOS transistor 201 can be fabricated using processing steps presently included in many CMOS foundry process flows. As a result, the LDMOS transistor 201 may be advantageously fabricated alongside conventional symmetrically configured CMOS devices. Consequently, and as shown by FIG. 2B, the LDMOS transistor 201 may be monolithically integrated with CMOS logic, such as by being fabricated on a semiconductor die 240 including a low voltage transistor 203.

FIG. 2B shows a cross-sectional view of a portion of the exemplary semiconductor die 240 including the low voltage transistor 203 and the LDMOS transistor 201 shown in FIG. 2A. The features of the LDMOS transistor 201 have been described above by reference to FIG. 2A. The low voltage transistor 203 includes a source 207, a source extension 217, a drain 209, a drain extension 219, a gate 211 disposed over a gate dielectric layer 213, and spacers 214 formed at the respective source-side and drain-side termini of the gate 211. Also shown in FIG. 2B are a body region 204 of the low voltage transistor 203 and an isolation body 238 electrically isolating the source 207 of the low voltage transistor 203 from the drain 208 and the drain-side N well 218 of the LDMOS transistor 201.

Corresponding features of the LDMOS transistor 201 and the low voltage transistor 203 can be fabricated concurrently using substantially the same materials and utilizing substantially similar processing steps. Thus, the sources 206 and 207 and the drains 208 and 209 can be implanted substantially concurrently using substantially the same dopant at substantially the same concentration. In addition, the source-side N well 236, the source extensions 216 and 217, the drain-side N well 218, and the drain extension 219 can each be implanted using dopants of the same conductivity type at a lower concentration.

The body contact 234 may be fabricated concurrently with implantation of highly doped source and drain regions of PMOS devices fabricated on the semiconductor die 240 (PMOS devices not shown in FIG. 2B). The source-side isolation body 232, the drain-side isolation body 220, and the isolation body 238, which may all be STI structures, may be substantially concurrently fabricated. Each of the gates 210 and 211, the gate dielectric layers 212 and 213, and the spacers 214 and 215 may be fabricated concurrently using the same or similar materials and techniques. Moreover, the deep N well implant 230 may be introduced into P type substrate 202 using existing CMOS processing techniques.

The low voltage transistor 203 may be a CMOS logic device. As shown in FIG. 2B, the body region 204 of the low voltage transistor 203 is electrically coupled to the P type substrate 202 and shares an electrical potential with the P type substrate 202. Due to the electrical coupling of the deep N well implant 230, the source-side N well 236, and the drain-side N well 218, the isolated body 205 of the LDMOS transistor 201 can be biased without affecting the electrical potential of the P type substrate 202. In addition, the electrical coupling of the deep N well implant 230, the source-side N well 236, and the drain-side N well 218 can shield the low voltage transistor 203 from noise generated during high voltage operation by the LDMOS transistor 201. As a result, the isolated body 205 of the LDMOS transistor 201 can be biased for high voltage operation with negligible or no affect on the performance of the low voltage transistor 203.

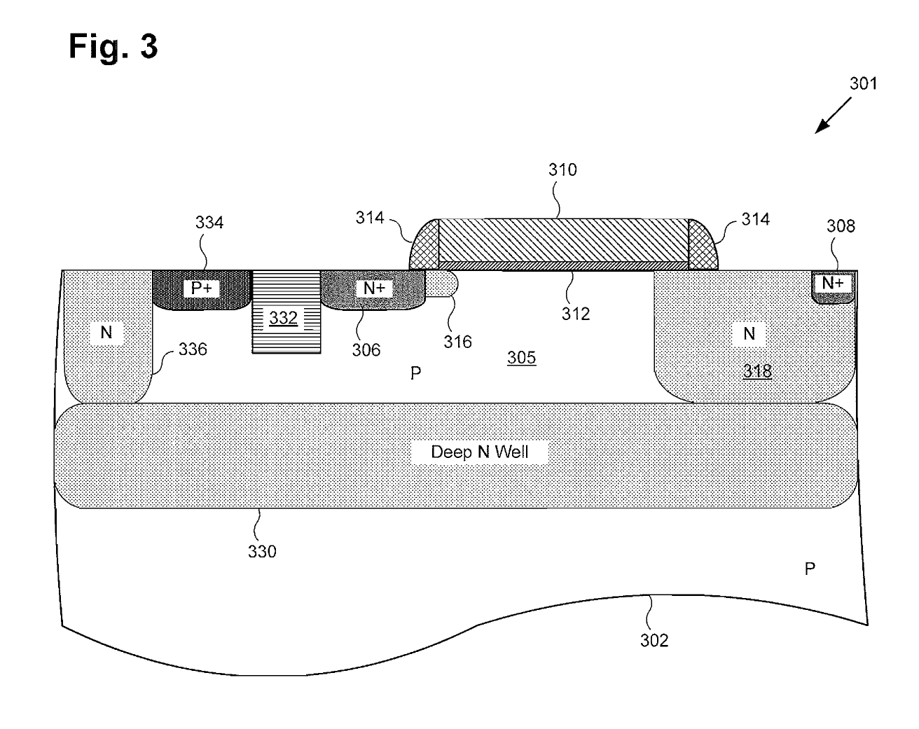

Referring to FIG. 3, FIG. 3 shows a cross-sectional view of another exemplary implementation of an LDMOS transistor 301 having an isolated body 305 for high voltage operation. The LDMOS transistor 301 corresponds in general to the LDMOS transistor 201, in FIGS. 2A and 2B. Moreover, the features of the LDMOS transistor 301 designated by reference numbers may have any of the characteristics previously attributed to the corresponding features of the LDMOS transistor 201 above.

Like the LDMOS transistor 201, the LDMOS transistor 301 is implemented as an NMOS device. Unlike the LDMOS transistor 201, however, the LDMOS transistor 301 omits a drain-side isolation body corresponding to the drain-side isolation body 220. As a result, the LDMOS transistor 301 has a reduced resistance to voltage breakdown when compared to the LDMOS transistor 201. Nevertheless, the body contact 334 may be used to bias the isolated body 305 for operation at a high (or low) voltage relative to the P type substrate 302, as well as relative to other devices fabricated in the P type substrate 302. Consequently, the LDMOS transistor 301 having the isolated body 305 can be used for high voltage operation such as for a high-side switch.

The LDMOS transistor 301 can be fabricated using processing steps presently included in many CMOS foundry process flows for producing NMOS devices. As a result, the LDMOS transistor 301 may be advantageously fabricated alongside conventional symmetrically configured CMOS devices. Consequently, like the LDMOS transistor 201 shown in FIGS. 2A and 2B, the LDMOS transistor 301 may be monolithically integrated with CMOS logic by being fabricated on a common semiconductor die.

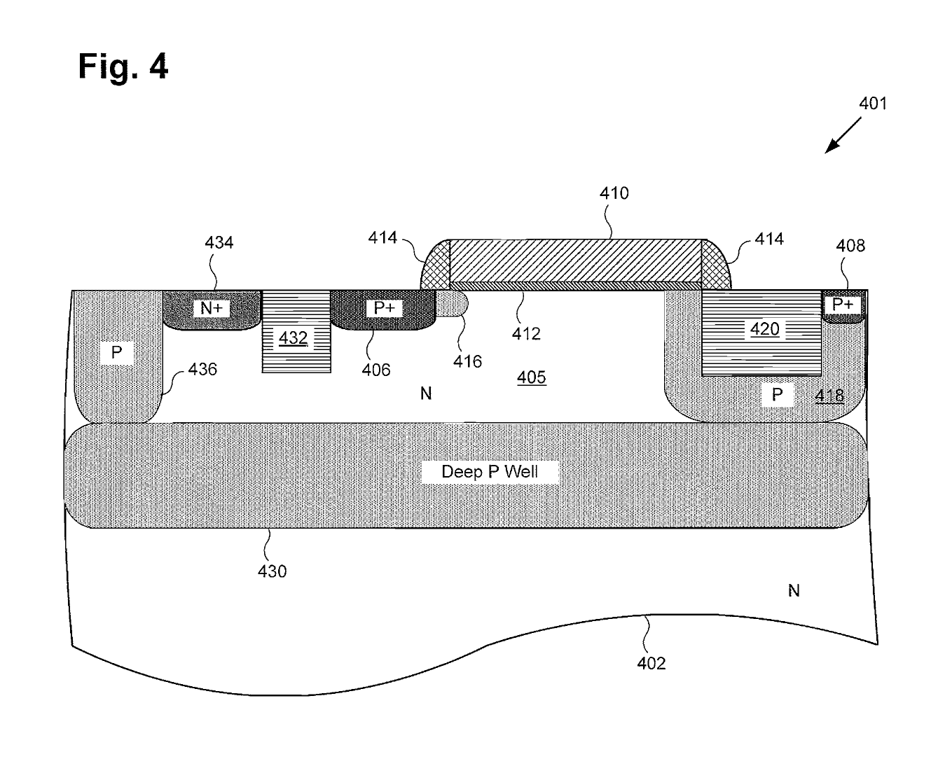

FIG. 4 shows a cross-sectional view of yet another exemplary implementation of an LDMOS transistor 404 having an isolated body 405 for high voltage operation. The LDMOS transistor 401 is fabricated in an N type substrate 402 of a semiconductor wafer or die. The N type substrate 302 may be an N well formed in a semiconductor wafer or die, or an N type epitaxial layer grown on the semiconductor wafer or die. The LDMOS transistor 401 includes a source 406, a source extension 416, a drain 408, a drain-side P well 418 serving as a drain extension region, and a drain-side isolation body 420 disposed in the drain-side P well 418. The LDMOS transistor 401 also includes a gate 410 disposed over a gate dielectric layer 412, and spacers 414 adjoining the respective source-side and drain-side termini of the gate 410. According to the implementation shown by FIG. 4, the source extension 416 and the drain-side P well 418 extend under the gate 410. However, the drain-side isolation body 420 is shown as being aligned with the drain-side terminus of the gate 410, and consequently does not extend under the gate 410.

The LDMOS transistor 401 is further shown to include a source-side P well 436, and a deep P well implant 430 electrically coupled to the source-side P well 436 and the drain-side-side P well 418. The electrically coupled arrangement of the deep P well implant 430, the source-side P well 436, and the drain-side P well 418 provides electrical isolation for the isolated body 405. As a result, the N type isolated body 405 is electrically isolated from the N type substrate 402. The electrically coupled arrangement of the deep P well implant 430, the source-side P well 436, and the drain-side P well 418 may also shield other devices fabricated on the N type substrate 402 from noise. For example, the isolated body 405 may result in CMOS logic devices fabricated in the N type substrate 402 being substantially shielded from noise generated by the LDMOS transistor 401. Also shown in FIG. 4 are a source-side isolation body 432 disposed between the source 406 and the source-side P well 436, and a body contact 434 disposed between the source-side isolation body 432 and the source-side P well 436.

The source 406 and the drain 408 are depicted as heavily doped P type regions, and may be produced through implantation of the N type isolated body 405 with a P type dopant such as boron (B). The gate 410 may be fabricated of conductive polysilicon, which may be LDD doped or heavily doped. Other examples of suitable gate materials are gate metals, which in the case of a PMOS implementation may include metals such as molybdenum (Mo), ruthenium (Ru), or tantalum carbide nitride (TaCN).

The gate 410 is disposed over the gate dielectric layer 412, which may be implemented as a gate oxide such as silicon dioxide (SiO₂). Other examples of suitable gate dielectrics for use as the gate dielectric layer 412 in combination with a highly doped polysilicon gate may include silicon nitride (Si₃N₄) or an oxynitride. Example dielectric materials suitable for use as the gate dielectric layer 412 with an LDD doped polysilicon gate, or a metal gate, include high-k metal oxides such as hafnium oxide (HfO₂), zirconium oxide (ZrO₂), or the like. The spacers 414 may be fabricated of any suitable dielectric material using any suitable technique, as known in the art. For example, the spacers 414 may he formed of silicon dioxide or silicon nitride using a CVD process.

The deep P well implant 430, the source-side P well 436, the source extension 416, and the drain-side P well 418 may be lightly doped P type regions produced through implantation of N type substrate 402 with a P type dopant such as boron. The source-side isolation body 432 and the drain-side isolation body 420 may be fabricated of any suitable dielectric material, and may be STI structures formed of silicon dioxide or TEOS. The body contact 434 is depicted as a heavily doped N type region, and may be produced through implantation of the N type isolated body 405 with an N type dopant such as arsenic (As) or phosphorus (P). The body contact 434 may be used to bias the isolated body 405 for operation at a low (or high) voltage relative to the N type substrate 402, as well as relative to other devices fabricated in the N type substrate 402.

The LDMOS transistor 401 can be fabricated using processing steps presently included in many CMOS foundry process flows for producing PMOS devices. As a result, the LDMOS transistor 401 may be advantageously fabricated alongside conventional symmetrically configured CMOS devices. Consequently, like the LDMOS transistor 201 shown in FIGS. 2A and 2B, the LDMOS transistor 401 may be monolithically integrated with CMOS logic by being fabricated on a common semiconductor die.

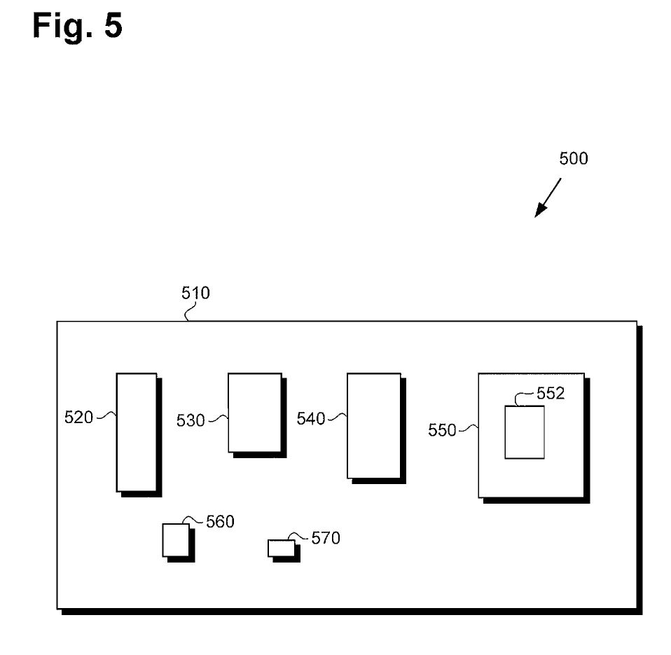

Continuing to FIG. 5, FIG. 5 shows a diagram of an exemplary electronic system 500 including an exemplary semiconductor die 540 utilizing at least one transistor having an isolated body for high voltage operation. In addition to the semiconductor die 540, the electronic system 500 includes exemplary modules 520 and 530, an integrated circuit (IC) chip 550 including an IC 552, and discrete components 560 and 570, residing in and interconnected through a printed circuit board (PCB) 510. In one implementation, the electronic system 500 may include more than one PCB.

The modules 520 and 530 are mounted on the PCB 510 and can each be a central processing unit (CPU), a graphics controller, a digital signal processor (DSP), an application specific integrated circuit (ASIC), or any other kind of module utilized in modern electronic circuit boards. The PCB 510 can include a number of interconnect traces (not shown in FIG. 5) for interconnecting the modules 520 and 530, the semiconductor die 540, the discrete components 560 and 570, and the IC chip 550.

The semiconductor die 540 corresponds to the semiconductor die 240 in FIG. 2B and may be implemented for analog or RF applications, such as in a PMU, a cellular telephone PA, or a WLAN PA. The discrete components 560 and 570 mounted on the PCB 510 can each be a discrete filter, an operational amplifier, a semiconductor device such as a transistor or a diode or the like, an antenna element, an inductor, a capacitor, or a resistor. Moreover, in some implementations, the discrete components 560 and 570 may themselves utilize a transistor having an isolated body for high voltage operation, as disclosed in the present application.

Thus, the present application discloses a deep well implant and source-side and drain-side wells electrically coupled to the deep well implant to produce a transistor having a body that is electrically isolated from the substrate in which it is fabricated. By virtue of that isolated body, the transistor may operate as a low noise device while being utilized as a high voltage power device. In addition, such an isolated body can enable use of the transistor as a high-side switch without substantially affecting electrical potential at other device locations on a shared die. Moreover, the present advantages can be realized using existing CMOS process flows, making integration of high voltage devices and CMOS devices efficient and cost effective. As a result, the present solution improves design flexibility without adding cost or complexity to established semiconductor device fabrication processes.

From the above description it is manifest that various techniques can be used for implementing the concepts described in the present application without departing from the scope of those concepts. Moreover, while the concepts have been described with specific reference to certain implementations, a person of ordinary skill in the art would recognize that changes can be made in form and detail without departing from the scope of those concepts. As such, the described implementations are to be considered in all respects as illustrative and not restrictive. It should also be understood that the present application is not limited to the particular implementations described above, but many rearrangements, modifications, and substitutions are possible without departing from the scope of the present disclosure.

1. A transistor comprising:
a deep well implant having a first conductivity type disposed in a substrate having a second conductivity type opposite said first conductivity type;
a source-side well and a drain-side well of said first conductivity type, said source-side well and said drain-side well electrically coupled to said deep well implant;
said deep well implant, said source-side well, and said drain-side well electrically isolating a body of said transistor from said substrate, said body having said second conductivity type;
a highly doped body contact having said second conductivity type disposed in said body adjacent to said source-side well.

2. The transistor of claim 1, wherein said transistor is an LDMOS transistor.

3. The transistor of claim 2, wherein said drain-side well is a drain extension region of said LDMOS transistor.

4. The transistor of claim 1, wherein said drain-side well includes a drain-side isolation body.

5. The transistor of claim 1, further comprising a source-side isolation body disposed between a source of said transistor and said source-side well, said source having said first conductivity type.

6. The transistor of claim 5, wherein said highly doped body contact is disposed between said source-side isolation body and said source-side well.

7. The transistor of claim 1, wherein said first conductivity type is N type and said second conductivity type is P type.

8. The transistor of claim 1, further comprising a metal gate disposed over a high-k dielectric layer disposed over said body of said transistor.

9. The transistor of claim 1, further comprising a polysilicon gate disposed over a gate oxide layer disposed over said body of said transistor.

10. The transistor of claim 9, wherein said polysilicon gate is a lightly doped polysilicon gate.

11. A transistor comprising:
a deep N well disposed in a P type substrate;
a source-side N well and a drain-side N well electrically coupled to said deep N well;
a drain-side isolation body disposed in said drain-side N well, said drain-side isolation body being substantially aligned with a gate of said transistor;
said deep N well, said source-side N well, and said drain-side N well electrically isolating a P type body of said transistor from said P type substrate;
a highly doped P type body contact disposed in said P type body adjacent to said source-side N well

12. The transistor of claim 11, wherein said transistor is an LDMOS transistor.

13. The transistor of claim 11, further comprising a source-side isolation body disposed between an N type source of said transistor and said source-side N well.

14. The transistor of claim 13, wherein said highly doped P type body contact is disposed between said source-side isolation body and said source-side N well.

15. A semiconductor die comprising:
a high voltage transistor and a low voltage device;
said high voltage transistor comprising:
a deep well implant having a first conductivity type disposed in a substrate of said semiconductor die having a second conductivity type opposite said first conductivity type;
a source-side well and a drain-side well of said first conductivity type, said source-side well and said drain-side well electrically coupled to said deep well implant;
said deep well implant, said source-side well, and said drain-side well electrically isolating a body of said high voltage transistor from said substrate of said semiconductor die, said body having said second conductivity type;
a highly doped body contact having said second conductivity type disposed in said body adjacent to said source-side well.

16. The semiconductor die of claim 15, wherein said body of said high voltage transistor is biased for high voltage operation.

17. The semiconductor die of claim 15, wherein said high voltage transistor is an LDMOS transistor.

18. The semiconductor die of claim 15, wherein said drain-side well of said high voltage transistor includes a drain-side isolation body aligned with a gate of said high voltage transistor.

19. The semiconductor die of claim 15, wherein said high voltage transistor further comprises a source-side isolation body disposed between a source of said high voltage transistor and said source-side well, said source having said first conductivity type.

20. The semiconductor die of claim 19, wherein said highly doped body contact is disposed between said source-side isolation body and said source-side well.
